(19) United States
(12) Patent Application Publication
(10) Pub. No.: US 2008/0231285 A1
(43) Pub. Date: Sep. 25, 2008

(54) Trailer Lighting, Control and Signaling Circuits Tester

(76) Inventor: Kevin Mark Curtis, Locust, NC (US)

Correspondence Address: QUICKPATENTS, INC., 32861 CALLE PERFECTO, SUITE A, SAN JUAN CAPISTRANO, CA, 92675, US

(21) Appl. No.: 11/949,928

(22) Filed: Dec. 4, 2007

Related U.S. Application Data
(60) Provisional application No. 60/918,771, filed on Mar. 19, 2007.

(51) Int. Cl. G01R 31/28; G08B 21/00

(52) U.S. Cl. 324/504; 340/431

(57) ABSTRACT

An electronic circuit tester is disclosed which is utilized for the testing and troubleshooting of the various lighting, control and signaling circuits required in the towing of a trailer, vehicle or other conveyance. The tester generally comprises an enclosure, which may be included as a part of a wiring harness connector, or separately attached to a wiring harness connector by means of electrical wiring. The testing circuit includes a plurality of input lines, logic means, and an alerting means. The testing circuits cause a distinct alert to be produced in response to each distinct test of the trailer device driving circuits of the vehicle.

### CROSS-REFERENCE TO RELATED APPLICATIONS

This application claims the benefit of U.S. Provisional Patent Application 60/918,771, filed on Mar. 19, 2007, and incorporated herein by reference.

### STATEMENT REGARDING FEDERALLY SPONSORED RESEARCH AND DEVELOPMENT

Not Applicable.

### FIELD OF THE INVENTION

This invention relates to circuit testers, and more particularly to a novel trailer lighting circuit tester.

### DISCUSSION OF RELATED ART

A variety of trailers and conveyances are being towed on public highways by automotive type trailer towing vehicles. These trailers and conveyances may consist of mobile homes, vans, or boat trailers, etc. which may be towed by automobiles, light trucks, or tractors, and the like. Government regulations require that towed trailers and conveyances be equipped with functional lighting, control, and signaling circuits similar to those on the towing vehicle. Using appropriate cables and plugs, these lighting, control, and signaling circuits are powered by the electrical connections between the trailer towing vehicle and the trailer or conveyance. It is essential that the operator of such trailer towing vehicles be able to quickly and accurately verify the correct operation of the lighting and signaling circuits that are connected from the towing vehicle to the towed trailer or conveyance.

Verification of the operation and wiring integrity of the umbilical circuits from a towing vehicle to its towed conveyance may be accomplished through the use of several prior art devices. Light emitting diodes (LED's) that attach to a towing vehicle's wiring harness with a plug are used by most of the present devices. The operator, after activating the lighting or control feature being tested, is then required to walk to the rear of the towing vehicle to verify that the correct LED of the test tool has been illuminated. Some test tools even activate an audible device to notify the tester that a signal is being received.

U.S. Pat. No. 5,414,362 to Gramling and Botkins on May 9, 1995, provides a device which verifies the operation of an electrical receptacle on a towing vehicle. The device utilizes an elongated insulated body containing light-emitting diodes in the rearward face connected to electrical contacts in the forward face. To conduct a test, the operator engages the device with a receptacle on the towed vehicle, and then activates each circuit from the driver's compartment. Illumination of the diodes verifies the operation of the electrical circuit connected to the forward face. With such a device the operator is required to walk back and forth from the towing vehicle's driver compartment to the rear of the vehicle to verify the results of testing operations.

U.S. Pat. No. 5,990,788 to Syracuse on Nov. 23, 1999, discloses an automotive trailer light tester which may be positioned between the respective plugs connecting a towing vehicle and a trailer. By utilizing an “OR” gate in combination with switches and an audio signal device, the device provides an audio signal to verify that each respective electrical signal is being properly transmitted. A single operator may verify the integrity of the wiring harness of the towing vehicle without leaving the driver's seat of the towing vehicle.

A limitation of LED type testing devices is that some circuits such as the brake lamp circuit must be depressed to energize their circuit. The correct operation of such circuits therefore cannot be verified by a single operator. Two persons are required to activate and verify operation of such a circuit using an LED type testing device.

A limitation of audible type testing tools is that the operator of such a tool is only aware that some circuit has been activated. While audible testing tools provide notice that some circuit was energized, they provide no information to the operator as to which circuit has been energized. No troubleshooting assistance is thereby provided to the operator.

Therefore, there is a need for a device that eliminates the need to walk back and forth from the towing vehicle's driver compartment to the rear of the vehicle to verify the results of testing operations. A device is also needed which will eliminate the need to have two persons available to conduct testing of the circuits. The new invention will enable one operator alone to test all of the functions of the umbilical wiring harness. The need to walk back and forth from the vehicle's driver compartment to the rear of the vehicle will be eliminated.

It is a further object of the present invention to assign each circuit tested a unique sound code. The new invention could utilize a micro-controller and be programmed to distinguish between various turn signals or other circuits by returning any combination of tones to identify any number of circuits being tested. The sound codes might consist of any unique combination of beeps and steady tones to identify correct operation of a particular circuit. The operator would then not only verify that some circuit had been activated, but also verify that a particular circuit had been activated.

Using tones to verify activation of the different circuits is useful as a troubleshooting tool in various instances. For example, the needed device would be programmed to indicate that more than one circuit was activated, indicating a “short” in the wiring. By implementing a micro-controller in the new invention, numerous methods may be devised to inform the operator as to which circuit is being activated, and which circuit is not functioning correctly. A further object of the present invention is thus to provide a “smart” troubleshooting aid for technicians, and to store and record the status information returned as a result of testing the trailer circuits.

### SUMMARY OF THE INVENTION

The present device is a new electronic device for the troubleshooting of the lighting, control and signaling circuits required when an automotive type vehicle is towing a trailer or other conveyance. The towing vehicle may include, but is not limited to, cars, trucks, tractor trailer (18 wheelers) recreational vehicles, tow trucks, and the like.

The new invention is simpler in construction, more universally usable and more versatile in operation than the prior art, and has many novel features not offered by the prior art devices. For example, the new invention provides distinct alerts for each trailer circuit tested, and does not require more than one operator to conduct testing of the trailer circuits.

The device can be configured to test the lighting, control and signaling circuits of any type of towed conveyance. The circuits being tested may include any type of wiring harness connector, i.e. 4, 5, 6, 7, 8 pin round or flat type connectors or the like.

The new invention generally consists of a small electronic enclosure, which may be included as a part of a wiring harness connector, or it may be attached to a wiring harness connector by means of electrical wiring. The device may or may not contain a battery compartment, as this is contingent upon the design of the circuit. An on-board battery may power the device or it may be powered by using parasitic power obtained from the host vehicle. The device may include electrical switches to possibly turn power on or off to the device or allow readout of stored information or any other functions required by the design of the electronic circuitry.

The circuit tester's small electronic enclosure contains the testing circuits. The invention engages an electrical connector of a vehicle, the connector being wired to the trailer device driver circuits. Each trailer device driver circuit powers at least one electronic trailer device. The invention's testing circuit includes a plurality of input lines, logic means, and an alerting means. The circuit tester logic means cause the alerting means to produce a plurality of distinct alerts.

An input connector is electrically connected to each input line of the trailer testing circuit, and is designed to mechanically and electrically engage the connector device of the vehicle. When the input connector is attached to the connector of the vehicle, the operator of the circuit tester then activates each of the trailer device driver circuits in turn. The testing circuits then cause a distinct alert to be produced by the alerting means in response to each distinct test of the trailer circuits.

Other features and advantages of the present invention will become apparent from the following more detailed description, taken in conjunction with the accompanying drawings, which illustrate, by way of example, the principles of the invention.

### DESCRIPTION OF THE DRAWINGS

FIG. 1 is a top view of the invention with the electronics enclosure integrated into the plug module itself;

FIG. 2 is a top view of the invention showing the embodiment where the electronic module and the plug module are separate units;

FIG. 3 is a perspective view of the invention with the electronics enclosure integrated into the plug module along with the terminations necessary for connection to the towed vehicle for use of the “open and short” detector section of the tester;

FIG. 4 is a top view of the invention showing the embodiment of a combination circuit tester and connector for a vehicle;

FIG. 5 is an electrical circuit diagram of the invention, showing the general electronics circuits needed to implement the invention, and showing the electrical input lines from the trailer towing vehicle; and

FIG. 6 is a perspective view of a wireless embodiment of the invention.

### DETAILED DESCRIPTION OF THE PREFERRED EMBODIMENT

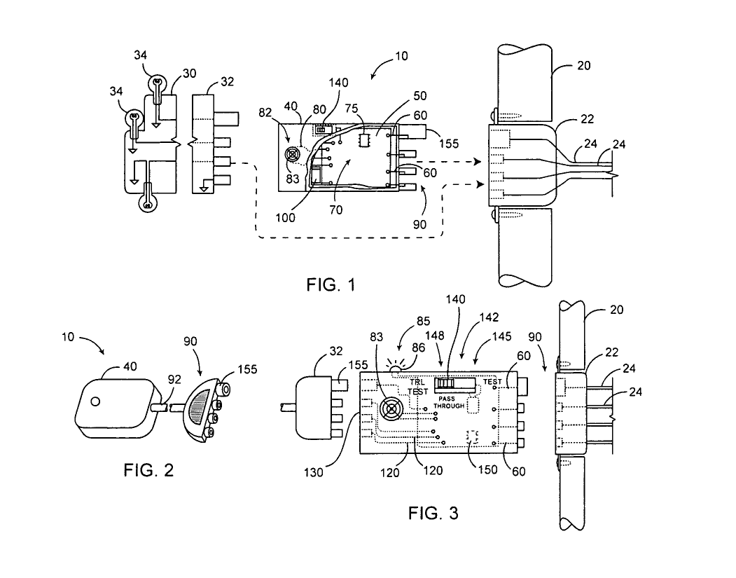

The present invention is a trailer lighting, control and signaling circuits tester 10 (FIGS. 1-3). The trailer towing vehicle 20 may include, but is not limited to, cars, trucks, recreational vehicles, tow trucks, and the like. The towed conveyance 30 may include, but is not limited to, utility trailers, recreational vehicles, other automobiles and trucks, large tractor-trailer type trailers, and the like.

The device 10 can be configured to test any type of towed conveyance lighting, control and signaling circuits, which may include any type of wiring harness connector 32, i.e. 4, 5, 6, 7, 8 pin round or flat type connectors 32.

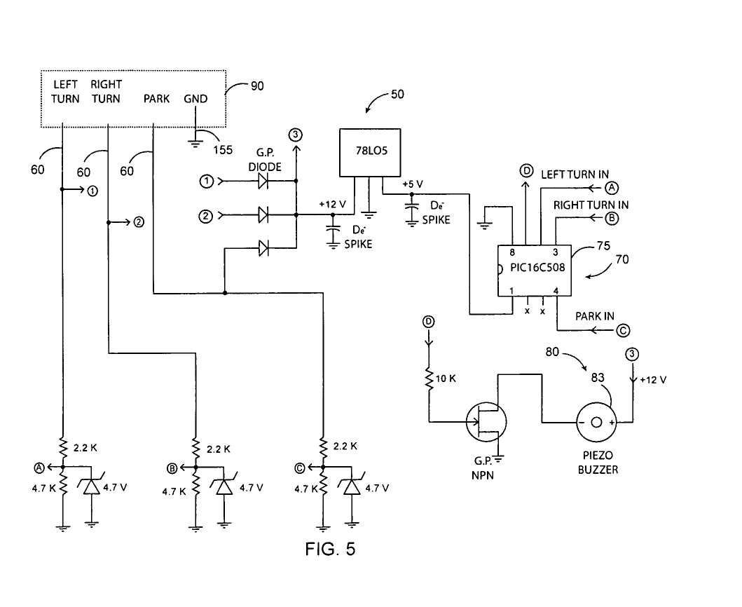

The circuit tester 10 is comprised of a small electronic enclosure 40 containing the testing circuit 50 (FIGS. 1 and 5). The circuit tester 10 engages an electrical connector 22 of a vehicle 20, the connector 22 being wired to the trailer device driver circuits 24 of the vehicle 20. Through a trailer connector 32 of the trailer 30, each trailer device driver circuit 24 powers at least one electronic trailer device 34. The testing circuit 50 includes a plurality of input lines 60, logic means 70, and an alerting means 80. The circuit tester logic means 70 cause the alerting means 80 to produce a plurality of distinct alerts. An input connector 90 is electrically connected to each input line 60 of the trailer testing circuit 50, and is designed to mechanically and electrically engage the connector 22 of the vehicle 20.

The small electronic enclosure 40 may be included as a part of a wiring harness connector 32, or it may be attached to a wiring harness connector 32 by means of electrical wiring. The connection to the towing vehicle wiring connector 32 is made by an input connector 90 (FIG. 1). Terminal 155 is typically a ground connection while is the remaining conductors 92 are function circuit connections for the lighting, signaling and control circuits.

The device 10 may or may not contain a battery 100, as this is contingent upon the design of the circuit 50 and the embodiment of the invention used. An on-board battery 100 may power the device 10, or it may be powered by using parasitic power obtained from the host vehicle 20. The device 10 may include an electrical pass-through switch 140 to turn power on or off to the device, allow readout of stored information, or any other functions required by the embodiment of the electronic circuit 50 used.

To conduct a test of the trailer driver circuits 24 on the towing vehicle 20, the circuit tester's input connector 90 is attached to the connector 22 of the vehicle 20. The operator of the circuit tester 10, while sitting in the driver compartment of the vehicle 20, then activates each of the trailer device driver circuits 24 in turn. The testing circuit 50 then causes the distinct alerts to be produced by the alerting means 80 in response to each distinct test of the trailer device driver circuits 24.

In one embodiment of the circuit tester 10, the logic means 70 is provided by a micro-controller 75 which is powered by any of the trailer device driver circuits 24. The alerting means 80 is provided by an audible alerting means 82, such as a piezoelectric audio transducer 83, for example.

Turning to the electrical circuit diagram of FIG. 5, the circuit tester 10 utilizes the micro-controller 75 as the logic means 70, inputs to which are controlled by each trailer device driver circuit 24. The trailer device driver lines from the input connector 90 are stabilized by 2.2K and 4.7K resistors, along with 4.7V zener diodes, before being input into a PIC 16C508 micro-controller 75, for example. The micro-controller 75 receives 5V power source via a 78L05 100 mA voltage regulator. The voltage regulator receives 12V input via several general-purpose diodes, while several de-spiking capacitors protect the input and output lines of the voltage regulator. The output of the micro-controller 75 controls a general purpose NPN transistor connected in line with the piezoelectric audio transducer 83.

Another embodiment of the invention utilizes a visual alerting means 85, which is comprised of at least one LED (light emitting diode) 86 (FIG. 3).

In still another embodiment of the invention, the input connector 90 of the circuit tester 10 is integrated into the enclosure 40 (FIG. 1). Alternately, the input connector 90 may be electrically connected to the circuit 50 through a conductor cable 92.

In FIG. 3, an embodiment of the circuit tester 10 includes a plurality of trailer input lines 120 electrically connected to an output connector 130. The output connector 130 is designed to mechanically and electrically engage the trailer connector 32. The pass-through switch 140 is electrically disposed between each trailer input line 120 and the output connector 130. In addition, at least one current testing means 150 (FIG. 3) is provided whereby the logic means 70 establishes through at least one current testing means a baseline impedance between each trailer input line 120 and a ground state 155 (FIG. 5). If the baseline impedance changes by a predetermined value, the logic means 70 activates the alerting means 80. The logic means 70 thereafter reestablishes the baseline trailer device impedance and deactivates the alerting means 80. As such, any change in baseline impedance is easily detected as an aid to troubleshooting short circuits in the trailer 30, for example.

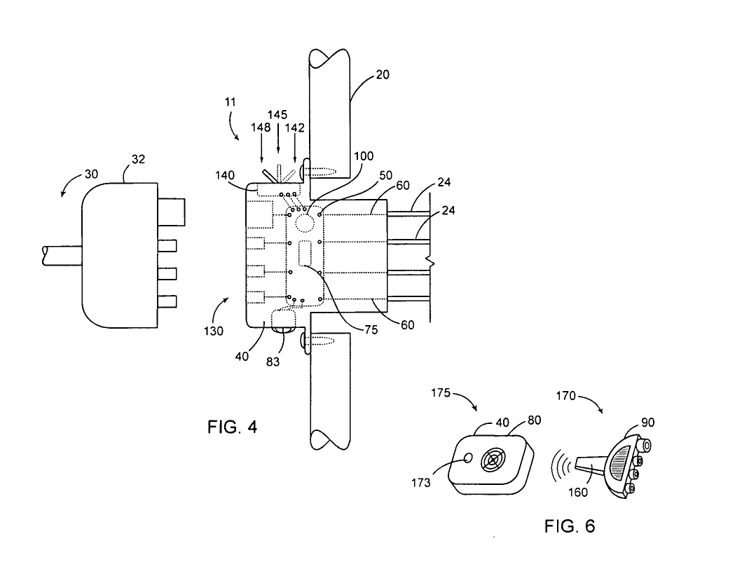

Turning now to FIG. 4, another embodiment of the invention comprises a combination circuit 11 tester and connector for the vehicle 20. In this embodiment the vehicle 20 has the plurality of trailer device driver circuits 24, each for powering at least one trailer device 34 through the trailer connector 32 of the trailer 30. Such a combination 11 is comprised of the enclosure 40 combined with the vehicle connector 22, which is electrically connected to each trailer device driver circuit 24 of the vehicle 20. The enclosure 40 is adapted to mechanically and electrically engage the trailer connector 32 of the trailer 30, and is further adapted to contain the testing circuit 50. This testing circuit 50 includes the plurality of input lines 60, the logic means 70, a test mode switch 140, and the alerting means 80. The logic means 70 is capable of causing the alerting means 80 to produce a plurality of distinct alerts. Each input line 60 is electrically connected to one of the trailer device driver circuits 24 of the vehicle 20. The test mode switch 140 disables the testing circuit in a “pass-through” position 142, and enables the testing circuit 50 in a “test” position 145. When the test mode switch 140 is in the “test” position, and each of the trailer device driver circuits 24 is activated in turn, the testing circuit 50 causes the alerting means 80 to produce each of the distinct alerts in turn.

The test mode switch 140 may also include a “trailer test” 148 position, connecting at least one current testing means 150 between the trailer device 34 and each trailer device driver circuit 24. The testing circuit 50, in such an embodiment, includes a plurality of trailer input lines 60 electrically connected to the vehicle connector 22. The logic means 70 establishes through the current testing means 150 a baseline impedance between each trailer input line 60 and a ground state 155. If such impedance changes by a predetermined value, the logic means 70 activates the alerting means 80. The logic means 70 thereafter reestablishes the baseline trailer device impedance and deactivates the alerting means 80.

In an alternate embodiment of the invention, illustrated in FIG. 6, the device 10 includes a transmitter module 170 that has a transmitter circuit 160, powered by the trailer device driver circuits 24 of the vehicle 20, and the input connector 90 electrically connected to input lines 60 of the transmitter circuit 160. A receiver module 175 is further included that can be held within the vehicle 20 by the user. The transmitter circuit 160 transmits a signal indicative of which trailer device driver circuit 24 is powered. Thereafter, the receiver module 175, which includes a radio receiving means (not shown) connected to the logic means 70, a battery means (not shown), and the alerting means 80, receives the transmitted signal and activates the alert means 80 as previously described. Such a receiver module 175 is powered by the battery means and may further include a power button or switch 173 that disconnects the battery means from the transmitter circuit 160.

In such an alternate embodiment as illustrated in FIG. 6, the logic means 70 may be alternately included in the transmitter module 170 instead of the receiver module 175. Further, the receiver module 175 may also include a plurality of the alert means 80, such as a plurality of LEDs (not shown), each for indicating one of the trailer device driver circuits 24.

While a particular form of the invention has been illustrated and described, it will be apparent that various modifications can be made without departing from the spirit and scope of the invention. For example, the invention could utilize both visual and audible alerting means. Likewise, in the wireless embodiment, the transmitter 160 may further include the output connector 130 and pass-through switch 140, as shown in FIG. 4. Accordingly, it is not intended that the invention be limited, except as by the appended claims.

What is claimed is:

1. A circuit tester for engaging a connector of a vehicle, the connector electrically connected to a plurality of trailer device driver circuits of the vehicle, each trailer device driver circuit for powering at least one electronic trailer device through a trailer connector of a trailer, the circuit tester comprising:
an enclosure adapted to contain a testing circuit, the testing circuit including a plurality of input lines, a logic means, and an alerting means, the logic means capable of causing the alerting means to produce a plurality of distinct alerts;
an input connector adapted to mechanically and electrically engage the connector of the vehicle and electrically connected to each input line of the testing circuit;
whereby with the input connector fixed to the connector of the vehicle and each of the trailer device driver circuits activated in turn, the testing circuit causes the alerting means to produce each of the distinct alerts in turn.

2. The circuit tester of claim 1 wherein the logic means is a microcontroller powered by each trailer device driver circuit.

3. The circuit tester of claim 1 wherein the alerting means is an audible alerting means.

4. The circuit tester of claim 3 wherein the alerting means is a piezoelectric audio transducer.

5. The circuit tester of claim 1 wherein the alerting means is a visual alerting means.

6. The circuit tester of claim 5 wherein the alerting means is at least one LED.

7. The circuit tester of claim 1 wherein the input connector is integrated into the enclosure.

8. The circuit tester of claim 1 wherein the input connector is electrically connected to each input line through a conductor cable.

9. The circuit tester of claim 1 wherein the testing circuit further includes a plurality of trailer input lines electrically connected to an output connector adapted to mechanically and electrically engage the trailer connector, a pass-through switch electrically disposed between each trailer input line and the output connector, and at least one current testing means, whereby the logic means establishes through the at least one current testing means a baseline impedance between each trailer input line and a ground state such that if the impedance changes by a predetermined value the logic means activates the alerting means, the logic means thereafter reestablishing the baseline trailer device impedances and deactivating the alerting means.

10. A combination circuit tester and connector for a vehicle, the vehicle having a plurality of trailer device driver circuits each for powering at least one trailer driver through a trailer connector of a trailer, comprising:
an enclosure having a vehicle connector electrically connected to each trailer device driver circuit of the vehicle and adapted to mechanically and electrically engage the trailer connector of the trailer, the enclosure further adapted to contain a testing circuit, the testing circuit including a plurality of input lines, a logic means, a test mode switch, and an alerting means, the logic means capable of causing the alerting means to produce a plurality of distinct alerts, each input line electrically connected to one of the trailer device driver circuits of the vehicle, the test mode switch disabling the testing circuit in a “pass-through” position and enabling the testing circuit in a “test” position;
whereby with the test mode switch in the “test” position and each of the trailer device driver circuits activated in turn, the testing circuit causes the alerting means to produce each of the distinct alerts in turn.

11. The combination of claim 10 wherein the logic means is a microcontroller powered by each trailer device driver circuit.

12. The combination of claim 10 wherein the alerting means is an audible alerting means.

13. The combination of claim 12 wherein the alerting means is a piezoelectric audio transducer.

14. The combination of claim 10 wherein the alerting means is a visual alerting means.

15. The combination of claim 14 wherein the alerting means is at least one LED.

16. The combination of claim 10 wherein the test mode switching further includes a “trailer test” position connecting at least one current testing means between the vehicle connector and each trailer device driver circuit, and wherein the testing circuit further includes a plurality of trailer input lines electrically connected to the vehicle connector, whereby the logic means may establish through each current testing means a baseline impedance between each trailer input line and a ground state such that if the impedance changes by a predetermined value the logic means activates the alerting means, the logic means thereafter reestablishing the baseline device impedances and deactivating the alerting means.

17. A circuit tester for engaging a connector of a vehicle, the connector electrically connected to a plurality of trailer device driver circuits of the vehicle, each trailer device driver circuit for powering at least one electronic trailer through a trailer connector of a trailer, the circuit tester comprising:
a transmitter module containing a transmitter circuit having a plurality of input lines and an input connector adapted to mechanically and electrically engage the connector of the vehicle, the input connector electrically connected to each input line of the transmitter circuit, the transmitter circuit adapted to send a radio frequency signal indicative of any of the plurality of input lines that is powered; and
a receiver module having a radio receiving means adapted to receive the transmission of the transmitter module, a logic means, a battery means, and an alerting means, the logic means powered by the battery means and capable of causing the alerting means to produce a plurality of distinct alerts based on the signal received from the transmitter module;
whereby with the input connector fixed to the connector of the vehicle and each of the trailer device driver circuits activated in turn, the transmitter circuit transmits the signal indicative of the trailer device driver circuit that is active, the logic means of the receiver module, receiving the signal, causing the alerting means to produce each of the distinct alerts in turn.
